(19) United States
(12) Patent Application Publication
(10) Pub. No.: US 2008/0024053 A1
(43) Pub. Date: Jan. 31, 2008

(54) THREE-DIMENSIONAL STRUCTURE, LIGHT EMITTING ELEMENT INCLUDING THE STRUCTURE, AND METHOD FOR MANUFACTURING THE STRUCTURE

(75) Inventors: Akira Fujimoto, Kawasaki-Shi (JP); Tsutomu Nakanishi, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Kabushiki Kaisha Toshiba, Tokyo (JP)

(21) Appl. No.: 11/687,854

(22) Filed: Mar. 19, 2007

(30) Foreign Application Priority Data
Jul. 26, 2006 (JP) 2006-203574

(51) Int. Cl. H01J 1/62; G02F 1/00; H01B 13/00

(52) U.S. Cl. 313/503; 216/13; 359/321

(57) ABSTRACT

It is made possible to provide a three-dimensional structure having a band-gap function as a three-dimensional photonic crystal. A three-dimensional structure includes: a plurality of basic elements provided at regular intervals on a substrate, each of the basic elements including a stack structure. The stack structure includes first members made of a dielectric material and second members made of the same dielectric material as the first members. The first and second members are alternately stacked, the second members each having a smaller diameter than each of the first members.

### CROSS-REFERENCE TO RELATED APPLICATION

This application is based upon and claims the benefit of priority from prior Japanese Patent Application No. 2006-203574 filed on Jul. 26, 2006 in Japan, the entire contents of which are incorporated herein by reference.

### BACKGROUND OF THE INVENTION

1. Field of the Invention

The present invention relates to a three-dimensional structure that is formed with a three-dimensional photonic crystal, a light emitting element including the three-dimensional structure, and a method for manufacturing the three-dimensional structure.

2. Related Art

A function of a three-dimensional photonic crystal is to generate a band gap, but, in practice, it is difficult to manufacture a three-dimensional structure with such a three-dimensional photonic crystal. As an example of a method for manufacturing a pseudo three-dimensional structure, JP-A 2001-272566 (KOKAI) discloses a method for manufacturing a three-dimensional structure. By this method, dielectric materials having different refractive index are stacked in a cyclic fashion, and patterning in the film plane direction is performed on the stacked dielectric materials, so as to form a two-dimensional regularly-arranged structure. By virtue of the difference in etching speed between the dielectric materials, a three-dimensional structure is formed in the film thickness direction that is perpendicular to the film plane direction.

However, in the three-dimensional structure produced by this method, the refractive index of the dielectric materials differ from each other. As a result, loss is caused, and an adequate band-gap function as a three-dimensional photonic crystal cannot be achieved.

As described above, a three-dimensional structure having an adequate band-gap function as a three-dimensional photonic function has not been produced to this date.

### SUMMARY OF THE INVENTION

The present invention has been made in view of these circumstances, and an object thereof is to provide a three-dimensional structure having a band-gap function as a three-dimensional photonic crystal, a light emitting element including the three-dimensional structure, and a method for manufacturing the three-dimensional structure.

A three-dimensional structure according to a first aspect of the present invention includes: a plurality of basic elements provided at regular intervals on a substrate, each of the basic elements including a stack structure, the stack structure comprising first members made of a dielectric material and second members made of the same dielectric material as the first members, the first and second members being alternately stacked, the second members each having a smaller diameter than each of the first members.

A light emitting element according to a second aspect of the present invention includes: a first electrode and a second electrode; an organic EL film that is provided between the first electrode and the second electrode; and a three-dimensional structure according to claim 1, the three-dimensional structure being provided on a face of one of the first and second electrodes, the face being on the opposite side from an emission direction of the organic EL film.

A light emitting element according to a third aspect of the present invention includes: a transparent substrate; a light emitting diode that is provided on the transparent substrate; and a three-dimensional structure according to claim 1, the three-dimensional structure being provided on a surface of the transparent substrate, the surface being on the opposite side from the surface on which the light emitting diode is provided.

A method for manufacturing the three-dimensional structure according to a fourth aspect of the present invention includes: forming a stack structure in which first layers containing a metal and second layers containing the metal are alternately stacked in a cyclic fashion on a substrate, the second layers having a different etching rate from the first layers; forming a two-dimensional regularly-arranged structure on the substrate by patterning the stack structure, the two-dimensional regularly-arranged structure being formed with stacked films consisting of the first layers and the second layers; forming a regularly-arranged structure in a direction perpendicular to the plane of the substrate by etching the first layers and the second layers of the two-dimensional regularly-arranged structure; and turning the first layers and the second layers into the same dielectric materials by oxidizing the etched first and second layers.

A method for manufacturing the three-dimensional structure according to a fifth aspect of the present invention includes: forming a stack structure in which first layers containing Si and second layers containing Si are alternately stacked in a cyclic fashion on a substrate, the second layers having a different etching rate from the first layers; forming a two-dimensional regularly-arranged structure on the substrate by patterning the stack structure, the two-dimensional regularly-arranged structure being formed with stacked films consisting of the first layers and the second layers; forming a regularly-arranged structure in a direction perpendicular to the plane of the substrate by etching the first layers and the second layers of the two-dimensional regularly-arranged structure; and turning the first layers and the second layers into the same dielectric materials by oxidizing the etched first and second layers.

### BRIEF DESCRIPTION OF THE DRAWINGS

FIG. 1 is a cross-sectional view of a three-dimensional structure in accordance with a first embodiment;

FIGS. 2A and 2B are plan views showing the two-dimensional arrangement of the basic elements in the three-dimensional structure of the first embodiment;

FIGS. 3A and 3B show the characteristics of the three-dimensional structure of the first embodiment;

FIGS. 4A and 4B show the characteristics of a three-dimensional structure as a comparative example of the first embodiment;

FIGS. 5A through 5D are cross-sectional views showing a first specific example of the method for manufacturing the three-dimensional structure of the first embodiment;

FIGS. 6A through 6D are cross-sectional views showing a second specific example of the method for manufacturing the three-dimensional structure of the first embodiment;

FIG. 7 is a cross-sectional view of an organic EL element in accordance with a second embodiment;

FIG. 8 is a cross-sectional view of a white LED in accordance with a third embodiment;

FIGS. 9A through 9C are cross-sectional views showing the procedures for manufacturing an organic EL element in accordance with Example 1 of the present invention;

FIGS. 10A through 10C are cross-sectional views showing the procedures for manufacturing an organic EL element in accordance with Example 1 of the present invention;

FIGS. 11A and 11B are cross-sectional views showing the procedures for manufacturing an organic EL element in accordance with Example 1 of the present invention;

FIGS. 12A through 12C are cross-sectional views showing the procedures for manufacturing an organic EL element in accordance with Example 2 of the present invention;

FIGS. 13A through 13C are cross-sectional views showing the procedures for manufacturing an organic EL element in accordance with Example 2 of the present invention;

FIGS. 14A through 14C are cross-sectional views showing the procedures for manufacturing an organic EL element in accordance with Example 2 of the present invention;

FIGS. 15A through 15C are cross-sectional views showing the procedures for manufacturing a light emitting diode in accordance with Example 4 of the present invention; and

FIGS. 16A and 16B are cross-sectional views showing the procedures for manufacturing a light emitting element in accordance with Example 4 of the present invention.

### DETAILED DESCRIPTION OF THE INVENTION

### First Embodiment

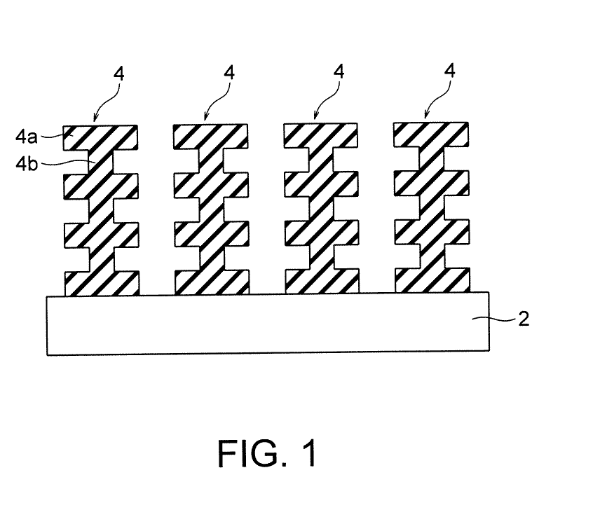

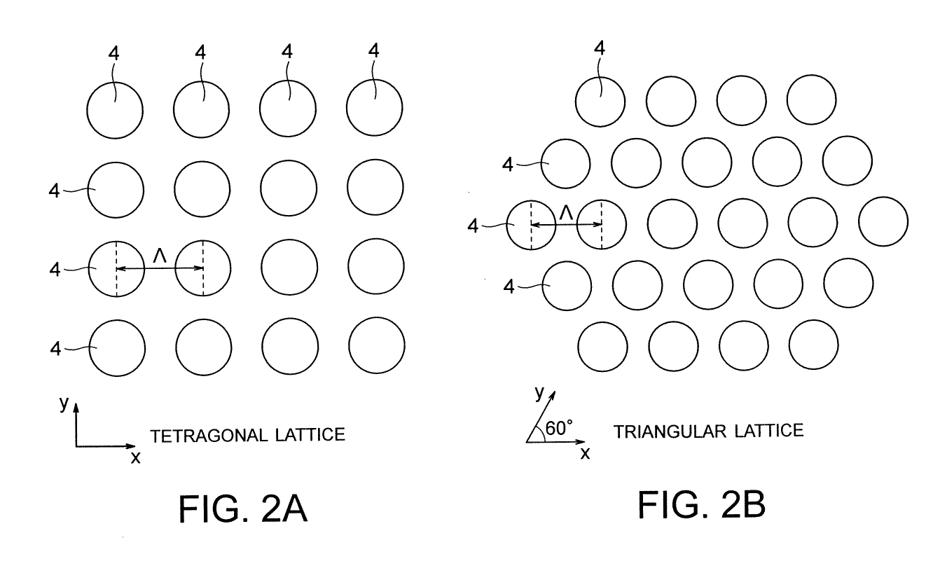

Referring to FIGS. 1 through 6D, a three-dimensional structure in accordance with a first embodiment of the present invention is described. As shown in FIG. 1, the three-dimensional structure 1 of this embodiment has basic elements 4 of identical structures arranged at regular intervals on a substrate 2. Here, the “basic elements 4 arranged at regular intervals on the substrate 2” means that the basic elements 4 being most closest are arranged at regular intervals Λ in at least one direction that is parallel to the plane of the substrate 2. For example, the basic elements 4 may be arranged at intervals Λ in a tetragonal lattice, as shown in FIG. 2A, or may be arranged at intervals Λ in a triangular lattice, as shown in FIG. 2B. FIGS. 2A and 2B each show a two-dimensional regularly-arranged structure having basic elements arranged at intervals in the x- and y-directions.

As shown in FIG. 1, each basic element 4 has a structure in which members 4a made of a dielectric material and members 4b made of the same dielectric material as the members 4a and having smaller diameters than the members 4a are alternately stacked in a direction perpendicular to the plane of the substrate 2. In other words, each basic element 4 has a regularly-arranged structure in the direction perpendicular to the plane of the substrate 2 (the film thickness direction). The intervals in the direction perpendicular to the plane of the substrate 2 may be different from the intervals Λ in the direction parallel to the plane of the substrate 2. In this embodiment, the shape of each of the members 4a and 4b in the film plane (the shape of the section of each of the members 4a and 4b in the plane parallel to the plane of the substrate 2) is circular. However, the members 4a and 4b may have polygonal shapes such as triangular shapes or tetragonal shapes, or some other shapes. In the case that the members 4a and 4b have shapes other than circular, its diameter (effective diameter) shall be understood as 2×(Shapes Area/π)^{0.5}.

As described above, the three-dimensional structure 1 of this embodiment has a two-dimensional regularly-arranged structure on the substrate 2 and regularly-arranged structures in the direction perpendicular to the plane of the substrate 2. Since the members 4a and 4b forming the regularly-arranged structures in the direction perpendicular to the plane of the substrate 2 (the film thickness direction) are made of the same dielectric material, the refractive index become uniform. Accordingly, no loss is caused in the band gap, and a three-dimensional structure having a band-gap function as a three-dimensional photonic crystal can be formed.

For ease of explanation of the effects of the three-dimensional structure of this embodiment as a photonic crystal, the two-dimensional regularly-arranged structure (the diffraction effect) and the stacked structures (the multilayer interference effect) of the three-dimensional structure are described independently of each other in the following.

First, the diffraction effect is described. In the following, the wave number vector of incoming light is represented by k₁, and the wave number vector of outgoing light is represented by k₂. With the grid intervals of the diffraction grating being Λ, the following relationship is established based on the diffraction theory:

k₁·sinθ₁+m(2π/Λ)=k₂·sinθ₂ (1)

where k₁ represents n₁×2π/λ, k₂ represents n₂×2π/λ, n₁ and n₂ represent the refractive index, θ₁ represents the incident angle, θ₂ represents the outgoing angle, and λ represents the emission wavelength.

In Equation (1), the “m“” in the second term of the left side represents the diffraction order and an integer. As can be seen from Equation (1), diffracted light is generated based on the lattice intervals in accordance with a certain wavelength. If appropriate lattice intervals are set, light transmission or a high reflection can be achieved by virtue of a diffraction effect, even under the conditions for high reflection or a high transmission. As examples of two-dimensional structures, FIGS. 2A and 2B show a tetragonal lattice and a triangular lattice, respectively. In FIGS. 2A and 2B, each of the parts forming the lattices has a circular shape, but it is not necessarily circular. Also, some other two-dimensional structure than those shown in FIGS. 2A and 2B, such as a honeycomb structure, may be employed as a periodic lattice.

Next, the multilayer interference effect is described. Where the refractive index of multilayer films having j (j≧2) stacked layers are n₁, n₂, . . . , nⱼ, and the film thicknesses are d₁, d₂, . . . , dⱼ from the light incoming side, the conditions for a high reflection can be determined by Equation (2):

nⱼdⱼcosθⱼ=λ/4 (2)

In Equation (2), θⱼ represents the incident angle. As can be seen from Equation (2), a high reflection can be achieved at a certain angle in a case of simple stacked films.

With the above diffraction effect being added to the multilayer films, a high reflection can be achieved in a wider range of angles. Accordingly, if an optimum structure is produced, a high reflection can be achieved at any incident angle.

The following is a description of comparisons between a three-dimensional structure of this embodiment having members 4a and members 4b that are made of the same dielectric material and form multilayer films, and a three-dimensional structure of a comparative example having multilayer films formed with members made of different dielectric materials (having different dielectric constants).

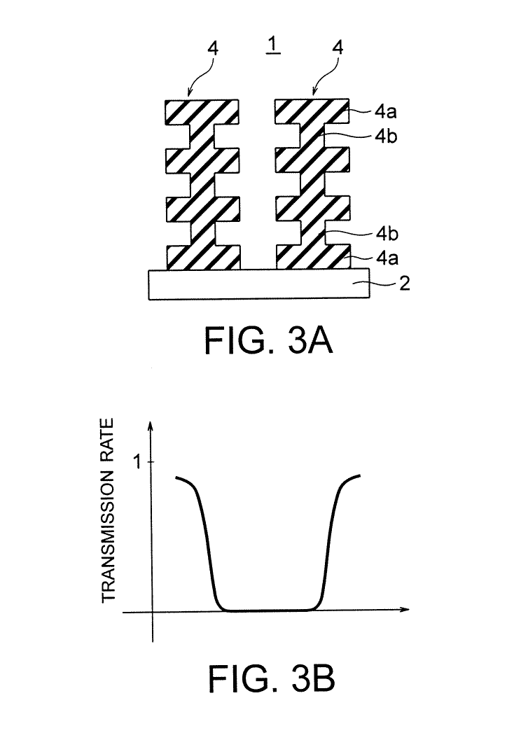

First, as shown in FIG. 3A, in this embodiment where the members 4a and the members 4b forming the multilayer films are made of the same dielectric material, a space that achieves a high reflection between the dielectric materials 4a and the air should be designed in accordance with Equation (2).

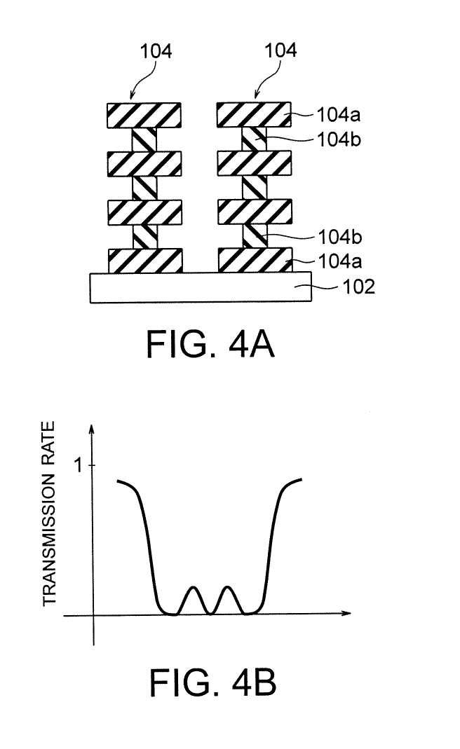

However, as shown in FIG. 4B, in the three-dimensional structure that has multilayer films 104 formed with members 104a and members 104b having different dielectric constants, two different conditions for high reflection need to be satisfied so as to achieve a high reflection between the dielectric members 104a and the air and a high reflection rate between the dielectric members 104a and the dielectric members 104b, which is fundamentally difficult.

Accordingly, in the case of the three-dimensional structure of this embodiment formed with the same dielectric materials, the transmission can be made almost zero in a certain range of wavelengths, as shown in FIG. 3B. In the case of the three-dimensional structure of the comparative example having different dielectric constants, a high reflection can be achieved in a certain range of wavelengths if the three-dimensional structure is designed properly. However, the reflection becomes low at a few points, as shown in FIG. 4B, due to the interference between the dielectric members 104a and the air, and the interference between the dielectric members 104a and the dielectric members 104b. Therefore, a three-dimensional structure having multilayer films formed with the members 4a and the members 4b made of the same dielectric material is more advantageous as a photonic crystal.

With the above facts being taken into account, a three-dimensional structure that is formed with the same dielectric members and has a highly reflective structure should preferably have a two-dimensional regularly-arranged structure of 50 nm to 1000 nm in size (the diameter of each of the members 4a) and have the intervals (Λ) of 100 nm to 2000 nm. In this three-dimensional structure, the regularly-arranged structures formed in the film thickness direction that is perpendicular to the two-dimensional regularly-arranged structure should preferably be arranged at intervals of 25 nm to 200 nm. Those preferred size and intervals are determined by Equations (1) and (2). The diameter of each of the members 4a is actually a diameter when the film face of each of the members 4a has a circular shape, but is the length of the longest diagonal line when each of the members 4a has a polygonal shape.

### (Manufacturing Method)

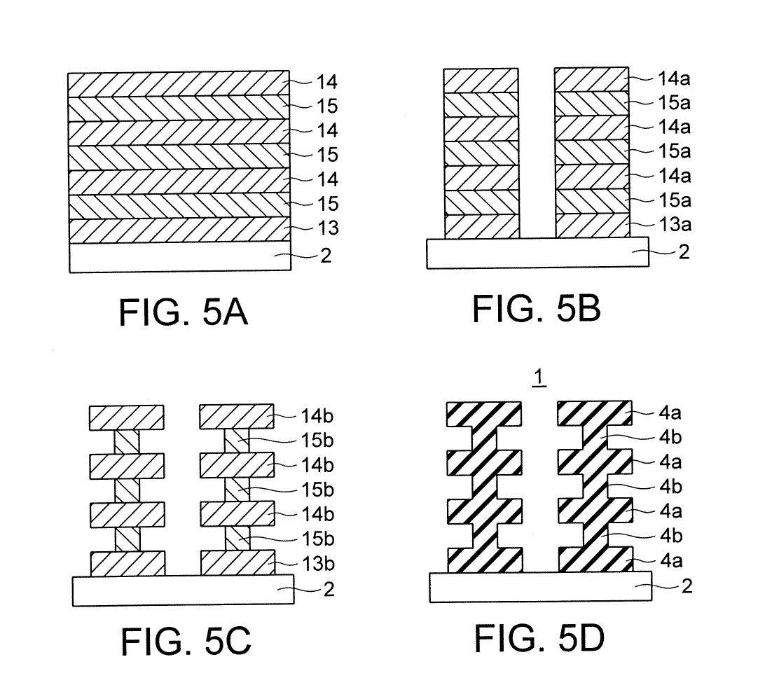

Referring now to FIGS. 5A through 5D, a first specific example of the method for manufacturing a three-dimensional structure of this embodiment is described.

First, as shown in FIG. 5A, an Al film 13 of 500 nm is formed as a reflecting mirror on the Si substrate 2 by a sputtering technique. After that, 100-nm thick AlF₃ films 15 as metal compound films, for example, and 100-nm thick Al films 14 as metal films, for example, are alternately stacked by a vapor deposition method. An electron beam resist is applied onto the stacked films of Al/AlF₃, and a resist pattern (not shown) having a two-dimensional pattern of 250 nm in size (the diameter of each member 4a) and 500 nm in interval (Λ) is formed with an electron beam exposure device that is equipped with a pattern generator and has an acceleration voltage of 50 kV. With this resist pattern serving as a mask, the stacked films is etched by RIE (Reactive Ion Etching) utilizing a Cl₂ gas. After the RIE, the remaining resist is removed by an O₂ asher, and a two-dimensional pattern of stack structures each consisting of an Al film 13a and stacked films of Al films 14a and AlF₃ films 15a is formed (see FIG. 5B).

Wet etching is then performed with phosphoric acid, so that a regularly-arranged pattern of stack structures each consisting of an Al film 13b and stacked films of Al films 14b and AlF₃ films 15b is formed in the stacking direction by virtue of the difference in etching rate between Al and AlF₃, as shown in FIG. 5C. After that, oxidation is performed in a vapor atmosphere at 150° C., so that the Al films 13b and 14b and AlF₃ films 15b are turned into Al₂O₃ films 4a and Al₂O₃ films 4b. In this manner, a three-dimensional structure 1 made of Al₂O₃ shown in FIG. 5D is produced.

By the above described manufacturing method as the first specific example, Al is used as a metal, and AlF₃ is used as a metal compound, so as to obtain a three-dimensional structure formed with dielectric members made of Al₂O₃. However, the present invention is not limited to the above combination of materials, but some other combination may be employed, as long as dielectric materials made of the same metal oxide are obtained after the oxidation. For example, a combination of Ti or TiO and TiO₂ may be employed so as to obtain a three-dimensional structure formed with dielectric members made of TiO₂. Alternatively, a combination of Mg and MgF₂ may be employed so as to obtain a three-dimensional structure formed with dielectric members of MgO, or a combination of La₂O₃ and LaF₃ may be employed so as to obtain a three-dimensional structure formed with dielectric members made of La₂O₃.

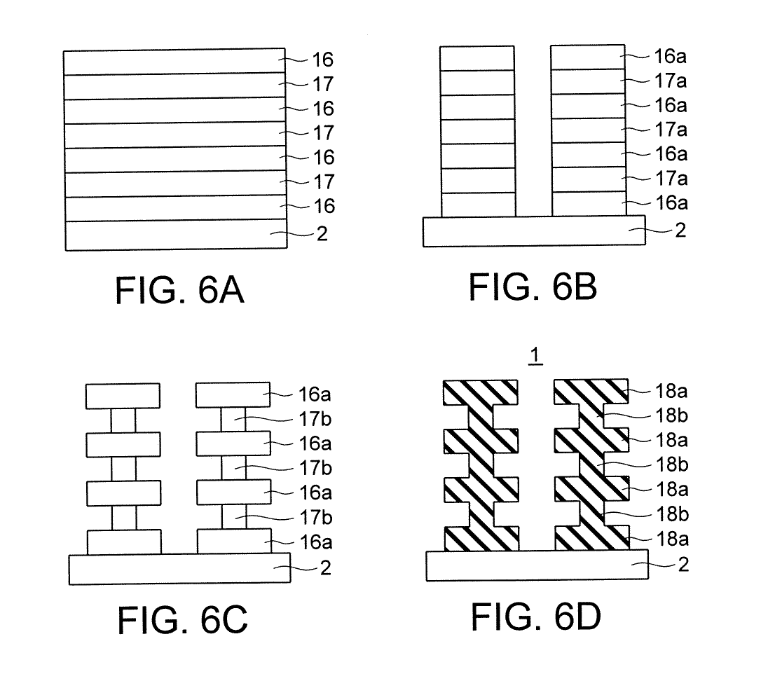

Referring now to FIGS. 6A through 6D, a second specific example of the method for manufacturing a three-dimensional structure of this embodiment is described.

First, as shown in FIG. 6A, SiO films 16 and Si films 17 are stacked on the Si substrate 2 by a sputtering technique. A resist pattern (not shown) is formed on the stacked SiO films 16 and Si films 17 in the same manner as in the first specific example. With this resist pattern serving as a mask, etching is performed on the stacked films by RIE (Reactive Ion Etching) utilizing a CF₄ gas. After the RIE, the remaining resist is removed by an O₂ asher, and a two-dimensional pattern of stacked films consisting of SiO films 16a and Si films 17a is formed (see FIG. 6B).

Wet etching is then performed with fluorinated acid, so that a regularly-arranged pattern of the SiO films 16a and Si films 17b is formed in the stacking direction, as the SiO films 16a are hardly etched but the Si films 17a are etched, as shown in FIG. 6C. After that, oxidation is performed in a vapor atmosphere at 600° C., so that the SiO films 16a and the Si films 17b are turned into SiO₂ films 18a and SiO₂ films 18b. In this manner, a three-dimensional structure 1 made of SiO₂ is produced as shown in FIG. 6D. Here, the Si substrate 2 is also oxidized to form a SiO₂ film 2.

In the first specific example, the difference in etching rate is utilized. In the second specific example, an etching solution with which one of the two materials cannot be etched is selected so as to produce a three-dimensional structure.

By the above described manufacturing method as the second specific example, the combination of Si and SiO is employed, so as to obtain a three-dimensional structure formed with dielectric members made of SiO₂. However, a combination of Si and SiO₂ or a combination of SiO and SiO₂ may be employed, so as to obtain a three-dimensional structure formed with dielectric members made of SiO₂.

As described above, by the method for manufacturing a three-dimensional structure of this embodiment, a three-dimensional structure having a large area can be readily produced.

A first example of an application of each of the above described three-dimensional structures is to an organic EL element of a top emission type, and a second example is to a white LED.

### Second Embodiment

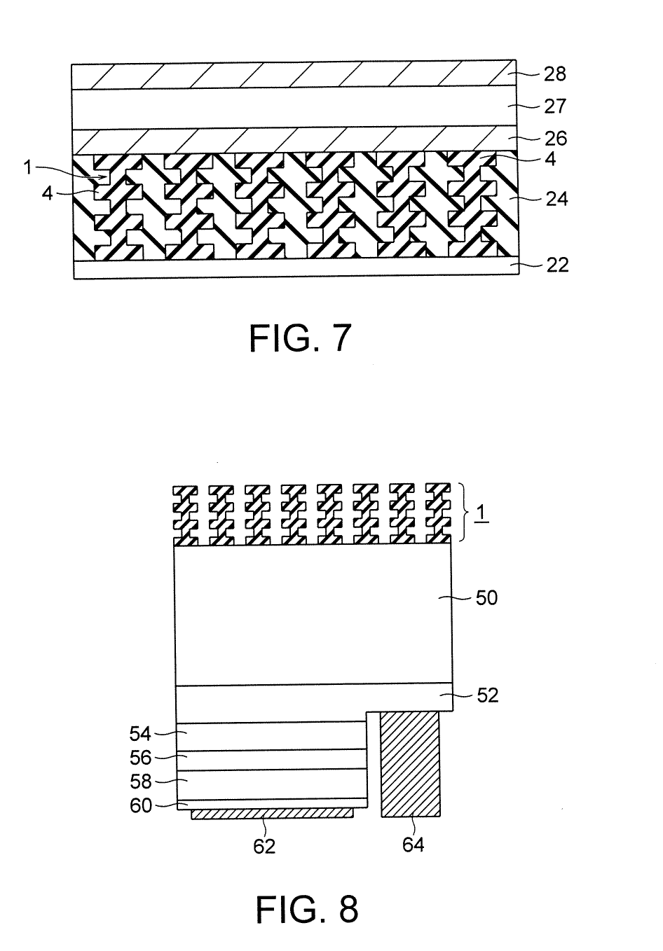

Referring now to FIG. 7, a second embodiment of the present invention is described. This embodiment is an organic EL element that includes a three-dimensional structure 1 of the first embodiment.

The organic EL element of this embodiment includes the three-dimensional structure 1 that has the basic elements 4 arranged at regular intervals on a reflecting plate 22 made of a metal and is formed with Al₂O₃ members, as described in First Embodiment. A SOG film 24 formed by baking spin on glass (SOG) is buried between the basic elements 4 of the three-dimensional structure 1. An anode 26 of a transparent electrode formed with an ITO having a film thickness of 150 nm is provided in contact with the Al₂O₃ of the three-dimensional structure 1. An organic EL film 27 that has a film thickness of 100 nm and is formed with a stack structure of a hole injection layer and an emission layer is provided on the anode 26. A cathode 28 of a transparent electrode having a film thickness of 150 nm is provided on the organic EL film 27.

In this embodiment, the three-dimensional structure 1 is formed in the opposite direction from the emission direction of the organic EL element. In this manner, the luminance can be greatly increased.

### Third Embodiment

Referring now to FIG. 8, a third embodiment of the present invention is described. This embodiment is a white LED that includes a three-dimensional structure 1 formed with Al₂O₃ members of the first embodiment.

A contact layer 52 made of n-Al_{0.4}Ga_{0.6}N, a cladding layer 54 made of n-Al_{0.35}Ga_{0.65}N, a SL activation layer 56 made of n-Al_{0.28}Ga_{0.72}N/n-Al_{0.24}Ga_{0.76}N, a SL cladding layer 58 made of p-Al_{0.4}Ga_{0.6}N/p-Al_{0.3}Ga_{0.7}N, and a contact layer 60 made of p-GaN are formed on a sapphire (single-crystal Al₂O₃) substrate 50. A p-type electrode 62 is formed on the contact layer 60, and an n-type electrode 64 is formed on the contact layer 52. This sapphire substrate is divided into chips to be light emitting diodes. Light emitted from the activation layer 56 is extracted from the surface of the sapphire substrate 50 on the opposite side from the cladding layer 52. The LED emission wavelength is within the ultraviolet region (300 nm to 400 nm). The basic structure described so far is the same as that of a conventional white LED. In this embodiment, however, a three-dimensional structure 1 is attached to the emission surface of the sapphire substrate 50, as shown in FIG. 8.

As described above, in accordance with this embodiment, a three-dimensional structure 1 is formed on the emission surface of the sapphire substrate of a white LED, so as to achieve much higher luminance.

A white LED in practice has a white fluorescent material in the form of a thin film formed on the emission surface of the LED, and the white fluorescent mateiral is sealed with epoxy resin.

The substrate of the white LED is made of Al₂O₃. The material of the three-dimensional structure should preferably have the same refractive index as that of the substrate, so as to prevent loss (reflection) at the interface between the substrate and the three-dimensional structure. In this aspect, this example differs from the example with an organic EL element. Accordingly, the material for the three-dimensional structure 1 employed in the white LED should preferably be Al₂O₃.

Next, the embodiments of the present invention are described in greater detail by way of examples.

### EXAMPLES

The following is a description of examples of the present invention.

In the following, an organic EL element is of a top emission type. In the organic EL element having an area of 1 cm², a three-dimensional structure is provided on the opposite side from the emission direction of the organic EL element. This organic EL element was compared with an organic EL element that did not include a three-dimensional structure, and evaluations were made on increases in luminance. In a white LED, a three-dimensional structure is provided on the surface on the opposite side from the LED element. This white LED was compared with a white LED that did not include a three-dimensional structure, and evaluations were made on increases in luminance.

### Example 1

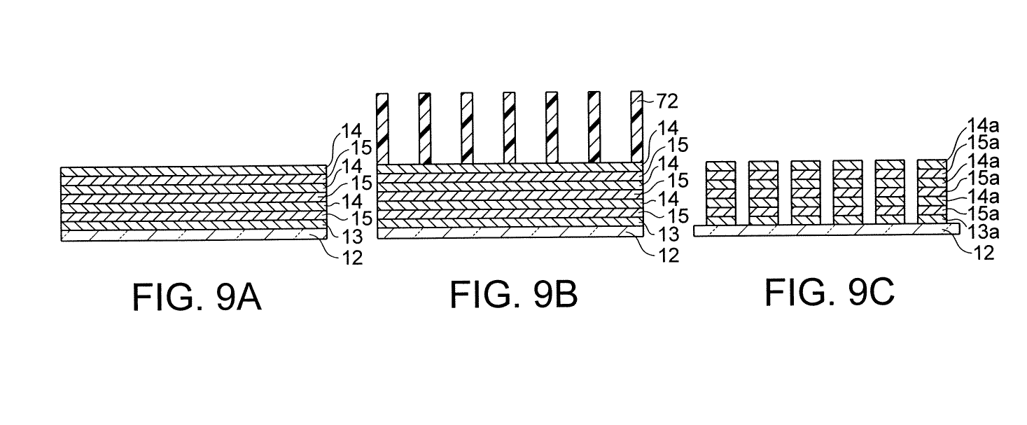

Referring now to FIGS. 9A through 11B, an organic EL element as Example 1 of the present invention is described.

After a 500-nm thick Al film 13 as a reflecting mirror was formed on a glass substrate 12 by a sputtering technique, three AlF₃ films 15 each having a film thickness of 90 nm and three Al films 14 each having a film thickness of 70 nm were alternately stacked by a vapor deposition method (see FIG. 9A).

A 500-nm thick electron beam resist was formed on the uppermost Al film 14. A resist pattern 72 having a two-dimensional regularly-arranged pattern of 300 nm in size and 600 nm in interval was formed with an electron beam exposure device that was equipped with a pattern generator and had an acceleration voltage of 50 kV (see FIG. 9B).

With this resist pattern 72 serving as a mask, the stacked films was etched by RIE using a Cl₂ gas for 10 minutes, with a flow rate of 30 sccm, a pressure of 1.33 Pa (10 mTorr), and a power of 100 W. After the RIE, the remaining resist was removed by an O₂ asher, and a two-dimensional regularly-arranged structure formed with a stack structure consisting of an Al film 13a and three-layer stack films of Al films 14a and AlF₃ films 15a was formed. The resist pattern 72 was then removed (see FIG. 9C).

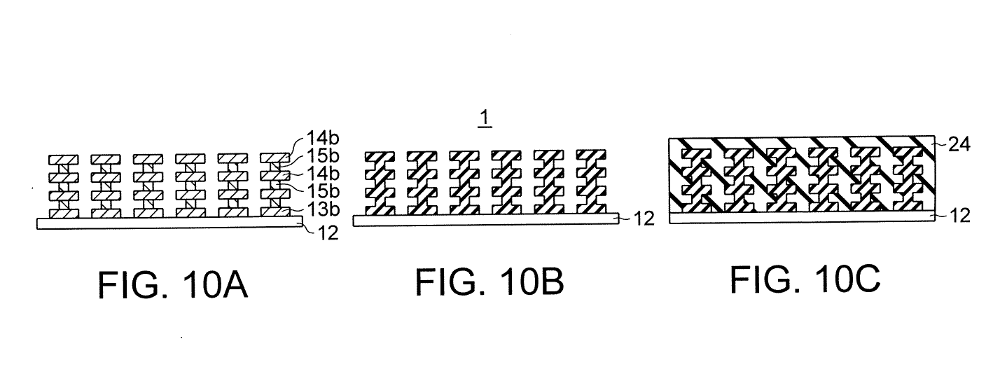

The stacked film after etched was wet-etched with the use of phosphoric acid for four minutes at room temperature. Accordingly, the Al films 13a and 14a were hardly etched, but 100 nm of each of the AlF₃ films 15a was etched from both side faces of the pattern. As a result, Al films 13b and 14b and AlF₃ films 15b were formed (see FIG. 10A).

After the phosphoric acid was removed, the stacked film was oxidized in a vapor atmosphere at 150° C. for 10 minutes, so that the Al films 13b and 14b and the AlF₃ films 15b were oxidized to form a three-dimensional structure 1 formed with Al₂O₃ members, as shown in FIG. 10B.

Spin on glass (SOG) as an organosilica was then applied at a rotation speed of 1000 rpm, and baking was performed at 150° C., so as to form a SOG film 24 having a film thickness of 600 nm. With the thickness of 600 nm, the surface of the SOG film 24 was flattened (see FIG. 10C).

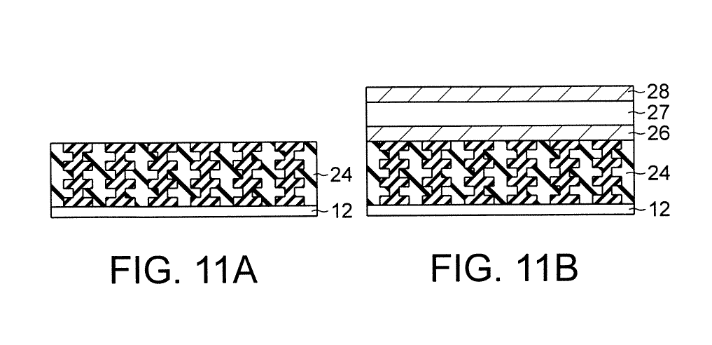

With the use of a CF₄ gas, the SOG film 24 was etched by RIE for one minute, with a flow rate of 30 sccm, a pressure of 1.33 pa (10 mTorr), and a power of 100 W. By doing so, the surfaces of the Al₂O₃ members forming the three-dimensional structure 1 were exposed (see FIG. 11A).

Flattening was then performed, and an ITO of 150 nm was deposited on the exposed Al₂O₃ members by a sputtering technique, so as to form an anode 26. A hole injection layer of N,N′-diphenyl-N,N′-bis(3-methylphenyl)1-1′biphenyl-4,4′diamine (hereinafter referred to as TPD) having a film thickness of 50 nm was deposited by a vapor deposition method on the ITO 26. An emission layer of Tris-(8-hydroxyquinoline)aluminum (hereinafter referred to as Alq3) having a film thickness of 100 nm was deposited on the hole injection layer by a vapor deposition method, so as to form an organic EL film 27. Lastly, an ITO of 150 nm was deposited by a sputtering technique, so as to form a cathode 28. Thus, the organic EL element shown in FIG. 11B was completed. Here, the peak wavelength was 530 nm.

The element produced in the above manner was evaluated to confirm a luminance 1.4 times higher than the luminance of an organic EL element that did not include a three-dimensional structure.

### Example 2

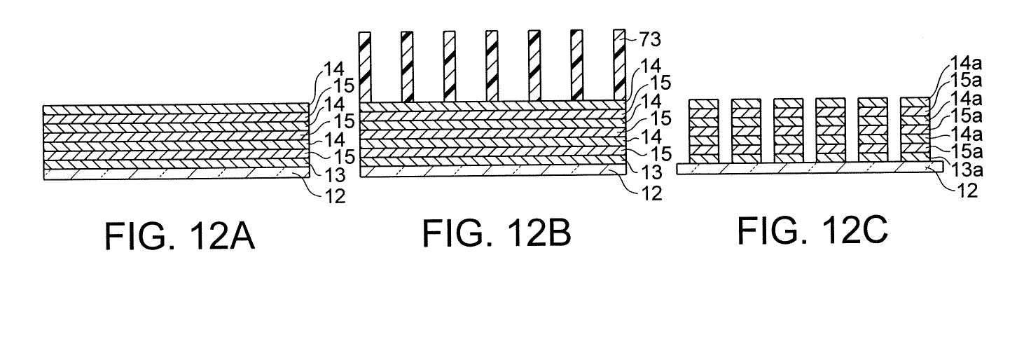

Referring now to FIGS. 12A through 14C, an organic EL element as Example 2 of the present invention is described.

As in the case of Example 1, after a 500-nm thick Al film 13 as a reflecting mirror was formed on a glass substrate 12 by a sputtering technique, three AlF₃ films 15 each having a film thickness of 120 nm and three Al films 14 each having a film thickness of 70 nm were alternately stacked by a vapor deposition method (see FIG. 12A).

A 500-nm thick electron beam resist was formed on the uppermost Al film 14. A resist pattern 73 having a two-dimensional regularly-arranged pattern of 400 nm in size and 800 nm in interval was formed with an electron beam exposure device that was equipped with a pattern generator and had an acceleration voltage of 50 kV (see FIG. 12B).

With this resist pattern 73 serving as a mask, the stacked films was etched by RIE using a Cl₂ gas for 10 minutes, with a flow rate of 30 sccm, a pressure of 1.33 Pa (10 mtorr), and a power of 100 W. After the RIE, the remaining resist was removed by an O₂ asher, and a two-dimensional regularly-arranged structure formed with a stack structure consisting of an Al film 13a and three-layer stack films of Al films 14a and AlF₃ films 15a was formed. The resist pattern 73 was then removed (see FIG. 12C).

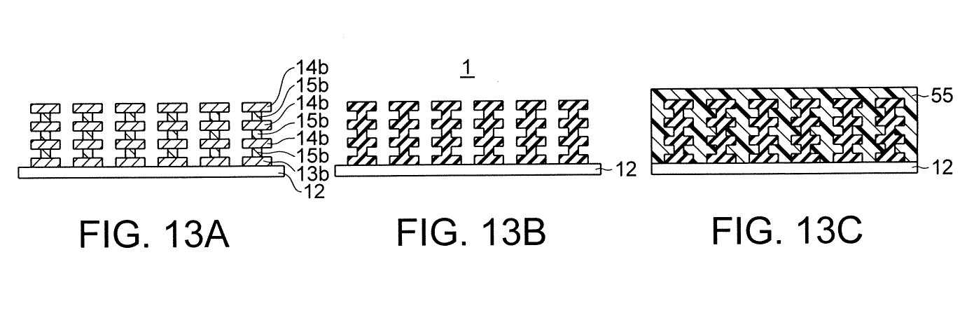

The stacked film after etched was wet-etched with the use of phosphoric acid for four minutes at room temperature. Accordingly, the Al films 13a and 14a were hardly etched, but 100 nm of each of the AlF₃ films 15a was etched from both side faces of the pattern. As a result, Al films 13b and 14b and AlF₃ films 15b were formed (see FIG. 13A).

After the phosphoric acid was removed, the stacked film was oxidized in a vapor atmosphere at 150° C. for 10 minutes, so that the Al films 13b and 14b and the AlF₃ films 15b were oxidized to form a three-dimensional structure 1 formed with Al₂O₃ members, as shown in FIG. 13B.

A polymethylmethacrylate (PMMA) solution was then applied at a rotation speed of 1000 rpm, and baking was performed at 100° C., so as to form a PMMA film 55 having a film thickness of 600 nm. With the thickness of 600 nm, the surface of the PMMA film 55 was flattened (see FIG. 13C).

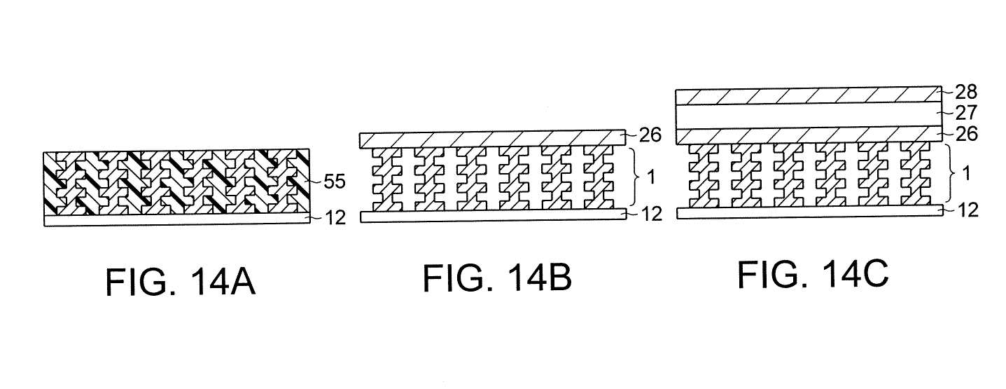

With the use of an O₂ gas, the PMMA film 55 was etched by RIE for one minute, with a flow rate of 30 sccm, a pressure of 1.33 pa (10 mTorr), and a power of 100 W. By doing so, the surfaces of the Al₂O₃ members forming the three-dimensional structure 1 were exposed (see FIG. 14A).

Flattening was then performed, and an ITO of 150 nm was deposited on the exposed Al₂O₃ members by a sputtering technique, so as to form an anode 26 (see FIG. 14B).

After the formation of the anode 26, baking was performed at 300° C., so as to resolve and remove the PMMA film 55 (see FIG. 14B). By doing so, the three-dimensional structure 1 formed with Al₂O₃ and the air was formed.

Next, a TPD film having a film thickness of 50 nm was deposited by a vapor deposition method. Alq3 as an emission layer having a film thickness of 100 nm was then deposited on the TPD film by a vapor deposition method, so as to form an organic EL film 27. Lastly, an ITO of 150 nm was deposited by a sputtering technique, so as to form a cathode 28. Thus, the organic EL element shown in FIG. 14C was completed. The peak wavelength of this organic EL element was 530 nm.

The element produced in the above manner was evaluated to confirm a luminance 1.8 times higher than the luminance of an organic EL element that did not include a three-dimensional structure. Since the difference in refractive index in the three-dimensional structure of this example was larger than that in Example 1, a larger increase in luminance was obtained.

### Example 3

Referring now to FIGS. 9A through 11B, an organic EL element as Example 3 of the present invention is described.

As in the case of Example 1, after a 500-nm thick Ti film 13 as a reflecting mirror was formed on a glass substrate 12 by a sputtering technique, three Ti films 14 each having a film thickness of 50 nm and three TiO₂ films 15 each having a film thickness of 90 nm were alternately stacked (see FIG. 9A).

A 1000-nm thick electron beam resist was formed on the uppermost Ti film 14. A resist pattern 72 having a two-dimensional regularly-arranged pattern of 300 nm in size and 600 nm in interval was formed with an electron beam exposure device that was equipped with a pattern generator and had an acceleration voltage of 50 kV (see FIG. 9B).

With this resist pattern 72 serving as a mask, the stacked films was etched by RIE using a Cl₂ gas for 20 minutes, with a flow rate of 30 sccm, a pressure of 1.33 Pa (10 mtorr), and a power of 100 W. After the RIE, the remaining resist was removed by an O₂ asher, and a two-dimensional regularly-arranged structure formed with a stack structure consisting of a Ti film 13a and three-layer stack films of TiO₂ films 15a and Ti films 14a was formed. The resist pattern 72 was then removed (see FIG. 9C).

The stacked film after etched was wet-etched with the use of phosphoric acid for five minutes at room temperature. Accordingly, the Ti films 13a and 14a were hardly etched, but 100 nm of each of the TiO₂ films 15a was etched from both side faces of the pattern. As a result, Ti films 13b and 14b and TiO₂ films 15b were formed (see FIG. 10A).

After that, the stacked film was oxidized in an oxygen atmosphere at 400° C. for 10 minutes, so that a three-dimensional structure 1 formed with TiO₂ members was formed, as shown in FIG. 10B.

Spin on glass (SOG) as an organosilica was then applied at a rotation speed of 1000 rpm, and baking was performed at 150° C., so as to form a SOG film 24 having a film thickness of 600 nm. With the thickness of 600 nm, the surface of the SOG film 24 was flattened (see FIG. 10C).

With the use of a CF₄ gas, the SOG film 24 was etched by RIE for one minute, with a flow rate of 30 sccm, a pressure of 1.33 pa (10 mTorr), and a power of 100 W. By doing so, the surfaces of the TiO₂ members forming the three-dimensional structure 1 were exposed (see FIG. 11A).

Flattening was then performed, and an ITO of 150 nm was deposited on the exposed TiO₂ members by a sputtering technique, so as to form an anode 26.

Next, a TPD film having a film thickness of 50 nm was deposited by a vapor deposition method. Alq3 as an emission layer having a film thickness of 100 nm was then deposited on the TPD film by a vapor deposition method, so as to form an organic EL film 27. Lastly, an ITO of 150 nm was deposited by a sputtering technique, so as to form a cathode 28. Thus, the organic EL element shown in FIG. 11B was completed. The peak wavelength of this organic EL element was 530 nm.

The element produced in the above manner was evaluated to confirm a luminance 1.9 times higher than the luminance of an organic EL element that did not include a three-dimensional structure. Since the refractive index of TiO₂ (=2.5) was higher than the refractive index of Al₂O₃, a larger increase in luminance than in Example 1 was obtained.

### Example 4

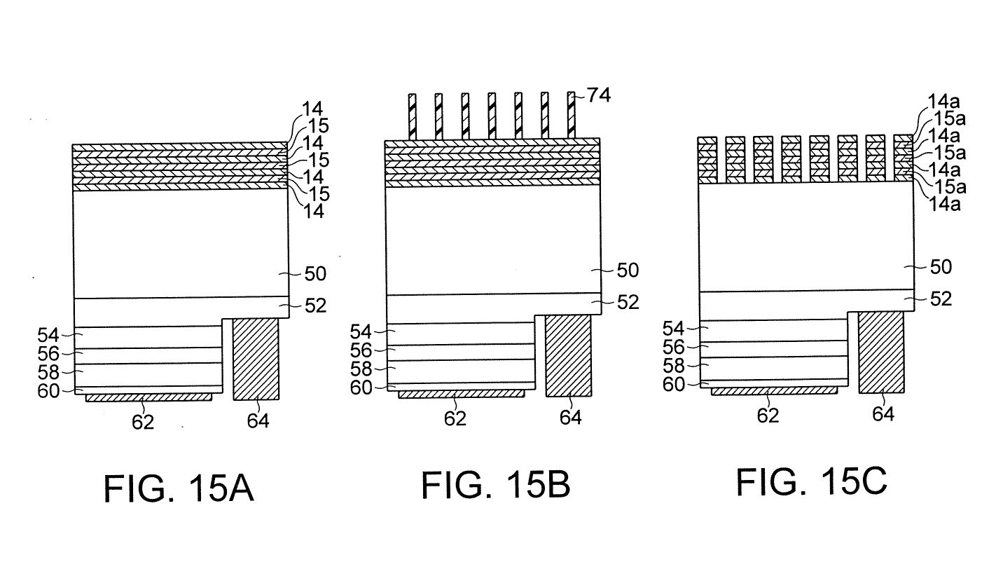

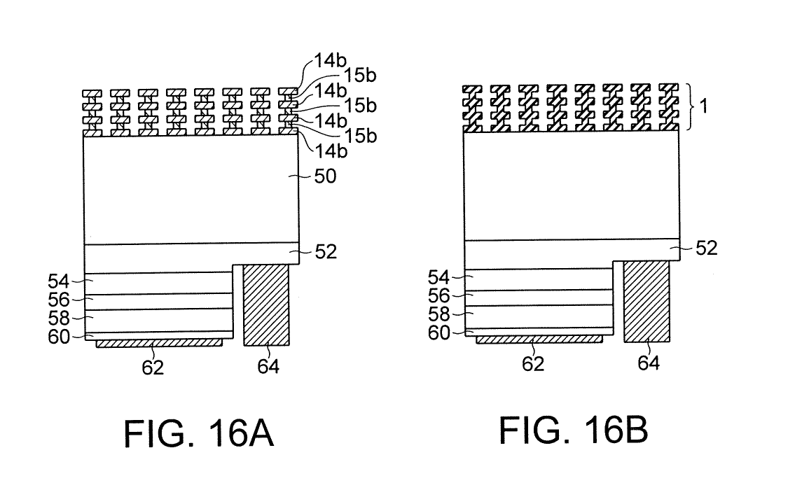

Referring now to FIGS. 15A through 16B, a LED as Example 4 of the present invention is described.

As shown in FIG. 15A, a contact layer 52 made of n-Al_{0.4}Ga_{0.6}N, a cladding layer 54 made of n-Al_{0.35}Ga_{0.65}N, a SL activation layer 56 made of n-Al_{0.28}Ga_{0.72}N/n-Al_{0.24}Ga_{0.76}N, a SL cladding layer 58 made of p-Al_{0.4}Ga_{0.6}N/p-Al_{0.3}Ga_{0.7}N, and a contact layer 60 made of p-GaN are formed on a sapphire (single-crystal Al₂O₃) substrate 50. A p-type electrode 62 is formed on the contact layer 60, and an n-type electrode 64 is formed on the contact layer 52.

Also, as shown in FIG. 15A, five Al films 14 each having a film thickness of 60 nm and five AlF₃ films 15 each having a film thickness of 100 nm were alternately stacked by a vapor deposition method on the surface of the sapphire substrate 50 on the opposite side from the cladding layer 52 (though only three layers each are shown in FIG. 15A).

A 500-nm thick electron beam resist was formed on the stacked films of Al/AlF₃. A resist pattern 74 of 150 nm in size and 300 nm in interval was formed with an electron beam exposure device that was equipped with a pattern generator and had an acceleration voltage of 50 kV (see FIG. 15B).

With this resist pattern 74 serving as a mask, the stacked films was etched by RIE using a Cl₂ gas for 10 minutes, with a flow rate of 30 sccm, a pressure of 1.33 Pa (10 mtorr), and a power of 100 W. After the RIE, the remaining resist was removed by an O₂ asher, and a two-dimensional regularly-arranged pattern having a stack structure formed with Al films 14a and AlF₃ films 15a was formed (see FIG. 15C).

The stacked film after etched was wet-etched with the use of phosphoric acid for two minutes at room temperature. Accordingly, the Al films 14a were hardly etched, but 50 nm of each of the AlF₃ films 15a was etched from both side faces of the pattern. As a result, Al films 14b and AlF₃ films 15b were formed (see FIG. 16A).

After that, the stacked film was oxidized in a vapor atmosphere at 150° C. for 10 minutes, so that a three-dimensional structure 1 formed with Al₂O₃ members was formed on the face through which light was emitted to the outside from the light emitting element, as shown in FIG. 16B.

The emission intensity of a ultraviolet ray (λ=360 nm) from the light emitting element of this embodiment was compared with the emission intensity of a ultraviolet ray (λ=360 nm) from a light emitting element as a comparative example that did not have a three-dimensional structure. As a result, the luminance of this example having a three-dimensional structure was about 70% higher than the luminance of the comparative example.

As opposed to the light emitting diode of this example that emits ultraviolet rays (UV-LED), a fluorescent material was mounted on the other surface of the substrate (the surface of the substrate on the opposite side from the surface on which the light emitting diode was formed), so as to form a white LED. The fluorescent material is shown in Table 1.

TABLE 1

| Fluorescent | | |
|---|---|---|
| Ratio | Color: Wavelength | Composition Material |
| ZnS:Cu, Al | green: λ = 530 nm | 22.80% |
| Y₂O₂S:Eu | red: λ = 626 nm | 55.80% |
| BaNgA11017:Eu | blue: λ = 454 nm | 21.40% |

This fluorescent material was provided in the form of a thin film on the emission surface of the LED, and was sealed with epoxy resin. The same fluorescent material was used for the light emitting diodes of this example and the comparative example, so as to form white LEDs. The luminance of white light emitted from the white LED of this example was compared with the luminance of white light emitted from the write LED of the comparative example. As a result, the luminance of the LED of this example was about 70% higher than the luminance of the comparative example.

### Example 5

Referring again to FIGS. 15A through 16B, a LED as Example 5 of the present invention is described.

As in the case of Example 4, five MgF₂ films 15 each having a film thickness of 100 nm and five Mg films 14 each having a film thickness of 60 nm were alternately stacked by a sputtering technique on a sapphire substrate 50 having LED films stacked thereon (see FIG. 15A).

A 500-nm thick electron beam resist was formed on the stack structure of Mg/MgF₂ films stacked by the sputtering technique. A resist pattern 74 having a two-dimensional regularly-arranged pattern of 150 nm in size and 300 nm in interval was formed with an electron beam exposure device that was equipped with a pattern generator and had an acceleration voltage of 50 kV (see FIG. 15B).

With this resist pattern 74 serving as a mask, the stacked films was etched by RIE using a Cl₂ gas for 10 minutes, with a flow rate of 30 sccm, a pressure of 1.33 Pa (10 mTorr), and a power of 100 W. After the RIE, the remaining resist was removed by an O₂ asher, and a two-dimensional regularly-arranged structure formed with Mg films 14a and MgF₂ films 15a was formed (see FIG. 15C).

The stacked film after etched was wet-etched with the use of hydrochloric acid for one minute at room temperature. Accordingly, the Mg films 14a were hardly etched, but 50 nm of each of the MgF₂ films 15a was etched from both side faces of the pattern. As a result, Mg films 14b and MgF₂ films 15b were formed (see FIG. 16A). After that, the stacked film was oxidized in an oxygen atmosphere at 300° C. for 30 minutes, so that a three-dimensional structure 1 formed with MgO members was formed (see FIG. 16B).

The emission intensity of a ultraviolet ray (λ=360 nm) from the light emitting element of this embodiment was compared with the emission intensity of a ultraviolet ray (λ=360 nm) from a light emitting element as a comparative example that did not have a three-dimensional structure. As a result, the luminance of this example having a three-dimensional structure was about 60% higher than the luminance of the comparative example. The refraction factor of MgO is almost the same as the refractive index of sapphire. Accordingly, the loss at the interface was small, while a high luminance was obtained.

As in the case of Example 4, a fluorescent material was provided in the form of a thin film on the emission surface of the LED, and was sealed with epoxy resin. The same fluorescent material was used for the light emitting diodes of this example and the comparative example, so as to form white LEDs. The luminance of white light emitted from the white LED of this example was compared with the luminance of white light emitted from the write LED of the comparative example. As a result, the luminance of the LED of this example having a three-dimensional structure was about 60% higher than the luminance of the comparative example.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concepts as defined by the appended claims and their equivalents.

What is claimed is:

1. A three-dimensional structure, comprising:
a plurality of basic elements provided at regular intervals on a substrate, each of the basic elements including a stack structure, the stack structure comprising first members made of a dielectric material and second members made of the same dielectric material as the first members, the first and second members being alternately stacked, the second members each having a smaller diameter than each of the first members.

2. The three-dimensional structure according to claim 1, wherein:
a diameter of the each of the first members of the basic elements is in the range of 50 nm to 1000 nm;
a distance between each two adjacent basic elements is in the range of 100 nm to 2000 nm; and
a sum of the thickness of one of the first members and the thickness of one of the second members stacked on the one of the first members is uniform and is in the range of 25 nm to 200 nm.

3. The three-dimensional structure according to claim 1, wherein the basic elements are arranged in the form of a tetragonal lattice or a triangular lattice on the substrate.

4. A light emitting element comprising:
a first electrode and a second electrode;
an organic EL film that is provided between the first electrode and the second electrode; and
a three-dimensional structure according to claim 1, the three-dimensional structure being provided on a face of one of the first and second electrodes, the face being on the opposite side from an emission direction of the organic EL film.

5. The light emitting element according to claim 4, wherein:
a diameter of the each of the first members of the basic elements is in the range of 50 nm to 1000 nm;
a distance between each two adjacent basic elements is in the range of 100 nm to 2000 nm; and
a sum of the thickness of one of the first members and the thickness of one of the second members stacked on the one of the first members is uniform and is in the range of 25 nm to 200 nm.

6. The light emitting element according to claim 4, wherein the basic elements are arranged in the form of a tetragonal lattice or a triangular lattice on the substrate.

7. A light emitting element comprising:
a transparent substrate;
a light emitting diode that is provided on the transparent substrate; and
a three-dimensional structure according to claim 1, the three-dimensional structure being provided on a surface of the transparent substrate, the surface being on the opposite side from the surface on which the light emitting diode is provided.

8. The light emitting element according to claim 7, wherein the transparent substrate is a sapphire substrate.

9. The light emitting element according to claim 7, wherein a fluorescent layer is provided between the transparent substrate and the three-dimensional structure.

10. The light emitting element according to claim 7, wherein:
a diameter of the each of the first members of the basic elements is in the range of 50 nm to 1000 nm;
a distance between each two adjacent basic elements is in the range of 100 nm to 2000 nm; and
a sum of the thickness of one of the first members and the thickness of one of the second members stacked on the one of the first members is uniform and is in the range of 25 nm to 200 nm.

11. The light emitting element according to claim 7, wherein the basic elements are arranged in the form of a tetragonal lattice or a triangular lattice on the substrate.

12. A method for manufacturing a three-dimensional structure, comprising:
forming a stack structure in which first layers containing a metal and second layers containing the metal are alternately stacked in a cyclic fashion on a substrate, the second layers having a different etching rate from the first layers;
forming a two-dimensional regularly-arranged structure on the substrate by patterning the stack structure, the two-dimensional regularly-arranged structure being formed with stacked films consisting of the first layers and the second layers;
forming a regularly-arranged structure in a direction perpendicular to the plane of the substrate by etching the first layers and the second layers of the two-dimensional regularly-arranged structure; and
turning the first layers and the second layers into the same dielectric materials by oxidizing the etched first and second layers.

13. The method according to claim 12, wherein the combination (M, A, B) of the metal M, a material A of the first layers and a material B of the second layers is one of (Al, Al, AlF₃), (Ti, Ti, TiO₂), (Ti, TiO, TiO₂), (Mg, Mg, MgF₂), and (La, La₂O₃, LaF₃).

14. A method for manufacturing a three-dimensional structure, comprising:
forming a stack structure in which first layers containing Si and second layers containing Si are alternately stacked in a cyclic fashion on a substrate, the second layers having a different etching rate from the first layers;
forming a two-dimensional regularly-arranged structure on the substrate by patterning the stack structure, the two-dimensional regularly-arranged structure being formed with stacked films consisting of the first layers and the second layers;
forming a regularly-arranged structure in a direction perpendicular to the plane of the substrate by etching the first layers and the second layers of the two-dimensional regularly-arranged structure; and
turning the first layers and the second layers into the same dielectric materials by oxidizing the etched first and second layers.

15. The method according to claim 14, wherein the combination (A, B) of a material A of the first layers and a material B of the second layers is one of (Si, SiO₂), (SiO, SiO₂), and (Si, SiO).
